(19) United States
(12) Patent Application Publication
(10) Pub. No.: US 2010/0074288 A1
(43) Pub. Date: Mar. 25, 2010

(54) SEMICONDUCTOR LASER DEVICE

(75) Inventor: Takeshi YAMAMOTO, Kyoto-shi (JP)

Correspondence Address: HAMRE, SCHUMANN, MUELLER & LARSON, P.C., P.O. BOX 2902, MINNEAPOLIS, MN, 55402-0902, US

(73) Assignee: ROHM CO., LTD., Kyoto-shi (JP)

(21) Appl. No.: 12/560,571

(22) Filed: Sep. 16, 2009

(30) Foreign Application Priority Data
Sep. 17, 2008 (JP) 2008-237551

(51) Int. Cl. H01S 5/022

(52) U.S. Cl. 372/43.01

(57) ABSTRACT

A semiconductor laser device of the present invention includes a plurality of semiconductor laser elements for emitting a laser beam, a stem and a plurality of leads. The stem includes a base portion and a block portion for supporting the semiconductor laser elements. The base portion includes at least one opening. Each of the leads extends through the opening of the base portion and is electrically connected to a respective one of the semiconductor laser elements. Two or more of the leads extend through one opening while being spaced from each other. The opening is filled with an insulating material.

### BACKGROUND OF THE INVENTION

1. Field of the Invention

The present invention relates to a semiconductor laser device which can be suitably used for an apparatus which utilizes a laser beam (e.g. laser printers).

2. Description of the Related Art

FIG. 5 illustrates a semiconductor laser device X2 as an example of conventional semiconductor laser device. The semiconductor laser device X2 includes a stem 91, a semiconductor laser element 92 and a light receiving element 93. The stem 91 is made up of a base portion 91A and a block portion 91B. The semiconductor laser element 92 and the light receiving element 93 are mounted on the block portion 91B. The base portion 91A is formed with two openings 91Aa. Leads 94A and 94B are arranged to extend through the openings 91Aa. The lead 94A is electrically connected to the semiconductor laser element 92 via a wire. The lead 94B is electrically connected to the light receiving element 93 via a wire. A lead 94C is bonded to the lower surface of the base portion 91A in the figure to provide a common terminal. A cap 95 is provided to cover the block portion 91B and upper portions of leads 94A, 94B in the figure. The lower end of the cap 95 in the figure is bonded to the base portion 91A by resistance welding. The cap 95 is formed with an opening 95a. The opening 95a is closed by a glass plate 96 attached to the cap 95. The glass plate 96 transmits the laser beam emitted from the semiconductor laser element 92. The openings 91Aa of the base portion 91A, through which the leads 94A and 94B extend, are filled with low-melting glass 97.

In the semiconductor laser device X2 having the above-described structure, the laser beam from the semiconductor laser element 92 is emitted upward in the figure. This type of semiconductor laser device is disclosed in JP-A-2004-31900, for example.

In the semiconductor laser device X2, the space S defined and separated from the outside mainly by the base portion 91A and the cap 95 (The openings 91Aa of the base portion 91A are filled with low-melting glass 97.) is kept airtight. With this arrangement, even when the semiconductor laser device X2 is used in a humid environment, the semiconductor laser element is not exposed to the humid environment. Thus, this arrangement is desirable for the protection of the semiconductor laser element 92.

In recent years, in accordance with the demand for high performance of an apparatus utilizing a laser beam (e.g. high printing speed of a laser printer), it is increasingly demanded that the semiconductor laser device X2 to be incorporated in such a laser beam utilizing apparatus provides high light emission output. As a means to increase the light emission output of the semiconductor laser device X2, to increase the number of semiconductor laser elements 92 has been proposed.

However, when the number of semiconductor laser elements 92 is increased in the semiconductor laser device X2, the number of leads 94A electrically connected to the semiconductor laser element 92 also needs to be increased correspondingly, and further, the number of openings 91Aa in the base portion 91A needs to be increased correspondingly. As noted before, the openings 91Aa are filled with low-melting glass 97 for achieving the airtightness of the space S. To properly load the low-melting glass 97 in the openings 91Aa, the opening area of each opening 91Aa needs to be sufficiently large. As the number of openings 91Aa, which are large enough to allow the proper loading of the low-melting glass 97, increases, the size of the base portion 91A increases. As a result, the semiconductor laser device X2 becomes large. Such a large semiconductor laser device X2 is not desirable, because the laser beam utilizing apparatus cannot be reduced in size when such a large semiconductor laser device is incorporated.

The present invention has been proposed under the circumstances described above. It is therefore an object of the present invention to provide a semiconductor laser device which is compact and achieves high light emission output.

### SUMMARY OF THE INVENTION

A semiconductor laser device provided according to the present invention includes a plurality of semiconductor laser elements for emitting a laser beam, a stem and a plurality of leads. The stem includes a base portion and a block portion for supporting the semiconductor laser elements. The base portion includes at least one opening. Each of the leads extends through the at least one opening of the base portion and is electrically connected to a respective one of the semiconductor laser elements. Two or more of the leads extend through one opening while being spaced from each other. The opening is filled with an insulating material.

Preferably, the opening has an elongated opening shape.

Preferably, each of the leads includes an end on a block portion side relative to the base portion. One of the ends that is relatively far from the block portion is positioned closer to the base portion than another one of the ends that is relatively close to the block portion.

Preferably, the base portion includes a plurality of openings including a first opening and a second opening each of which has an elongated opening shape. Each of the first and the second openings includes a first end at one end in the longitudinal direction of the opening shape and a second end at the other end in the longitudinal direction of the opening shape. The first and the second openings are spaced from each other so that the respective first ends face each other and the respective second ends face each other. The block portion is positioned on the base portion at a position between the first ends. The distance between the second ends is smaller than the distance between the first ends.

Preferably, the base portion and the block portion are made of a conductive material. The semiconductor laser device, in this case, further includes a common lead attached to a side of the base portion that is opposite the block portion and electrically connected to the semiconductor laser elements via the base portion and the block portion.

Preferably, each of the leads is smaller in cross sectional area than the common lead.

Preferably, the semiconductor laser device of the present invention further includes a light receiving element and an additional lead electrically connected to the light receiving element. The light receiving element is supported by the stem. The base portion of the stem, in this case, includes an additional opening. The additional lead extends through the additional opening. The additional opening is filled with an insulating material.

### BRIEF DESCRIPTION OF THE DRAWINGS

FIG. 1 is a front view illustrating a semiconductor laser device according to the present invention;

FIG. 2 is an enlarged front view, partially omitted, illustrating a portion of the semiconductor laser device according to the present invention;

FIG. 3 is an enlarged plan view, partially omitted, illustrating the semiconductor laser device according to the present invention;

FIG. 4 is a sectional view taken along lines IV-IV in FIG. 3; and

FIG. 5 is a sectional view illustrating a conventional semiconductor laser device.

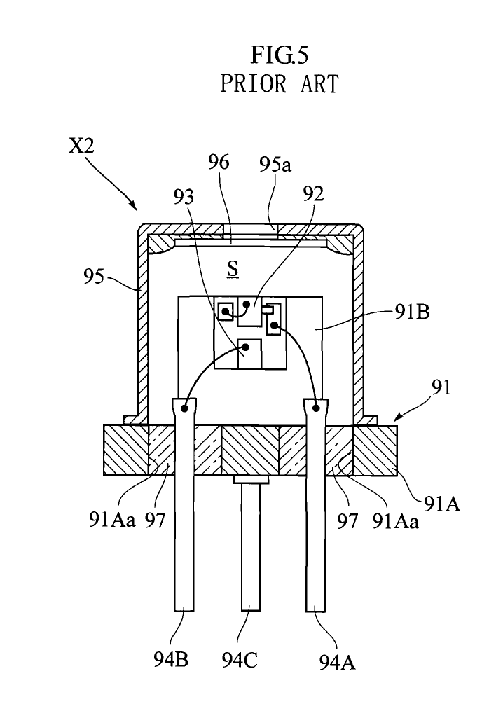

### DETAILED DESCRIPTION OF THE PREFERRED EMBODIMENTS

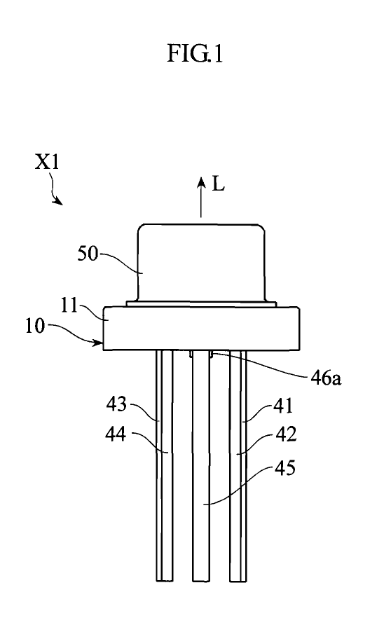

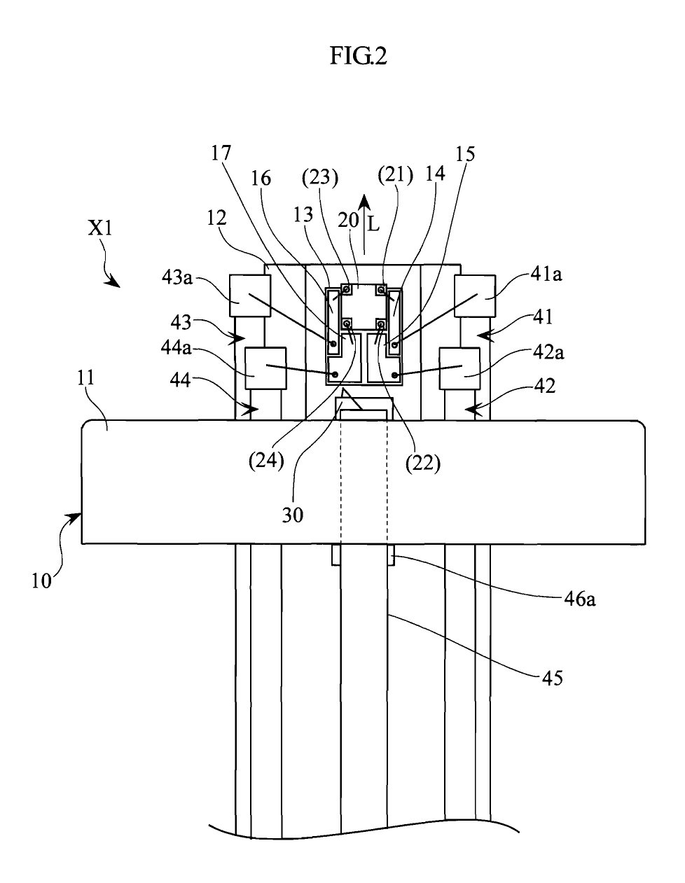

The semiconductor laser device X1 includes a stem 10, a laser emitting portion 20, a light receiving element 30, leads 41, 42, 43, 44, 45, 46, a cap 50 (not shown in FIGS. 2 through 4) and insulating material portions 60. The semiconductor laser device is designed to emit a laser beam in the direction L indicated in FIGS. 1, 2 and 4.

The stem 10 includes a base portion 11 and a block portion 12. In this embodiment, the base portion 11 and the block portion 12 are made of a conductive material as an integral unit. The conductive material may be Cu or Cu alloy. The base portion 11 is substantially disc-shaped. The block portion 12 is in the form of a hexagonal prism and located on the base portion 11 at a position shifted radially outward from the center of the base portion 11. The diameter of the base portion 11 is e.g. 5.6 mm. The thickness of the base portion 11 is e.g. 1.2 mm.

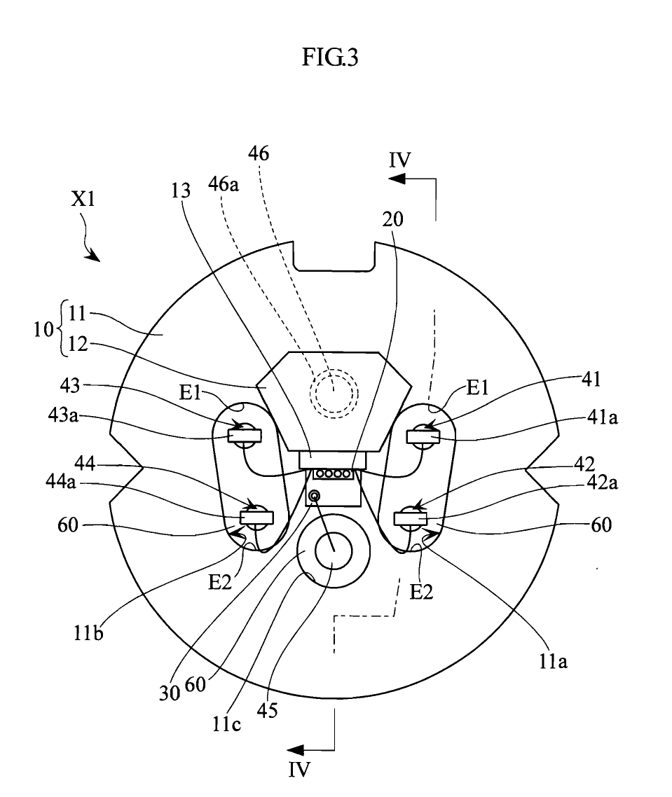

The base portion 11 includes three openings 11a, 11b, and 11c. As illustrated in FIG. 3, the openings 11a and 11b have an elongated opening shape, whereas the opening 11c has a circular opening shape. The openings 11a and 11b are spaced from each other, with the block portion 12 and the opening 11c intervening between the openings 11a and 11b. Specifically, the openings 11a and 11b are so arranged that, the block portion 12 is positioned on the base portion 11 at a position between respective ends E1 of the openings 11a and 11b, which are the ends on the block portion 12 side, whereas the opening 11c is positioned between respective ends E2 of the opening 11a and 11b, which are the ends opposite the ends E1. The distance between the ends E2 is smaller than that between the ends E1.

The block portion 12 has a side surface provided with a submount 13. The submount 13 may be a silicon substrate or an AlN (aluminum nitride) substrate. As illustrated in FIG. 2, the laser emitting portion 20 and four pads 14, 15, 16, 17 spaced from each other are mounted on the submount 13.

The laser emitting portion 20 includes four semiconductor laser elements 21, 22, 23, 24 which emit a laser beam individually. In FIG. 2, the reference signs for the semiconductor laser elements point to the pads electrically connected to the semiconductor laser elements. The semiconductor laser elements 21, 22, 23, 24 are electrically connected to the pads 14, 15, 16, 17 via wires, respectively. A laser beam is emitted from the upper end of the laser emitting portion 20 in FIG. 2 in the direction L, while a monitoring laser beam is emitted from the lower end of the laser emitting portion 20 in FIG. 2 in the direction opposite to the direction L.

The light receiving element 30 is an element (e.g. a pin photo diode) which outputs a signal having a magnitude corresponding to the light intensity of the light received by the light receiving element 30. The light receiving element is provided on the base portion 11 in a region between the openings 11a and 11b.

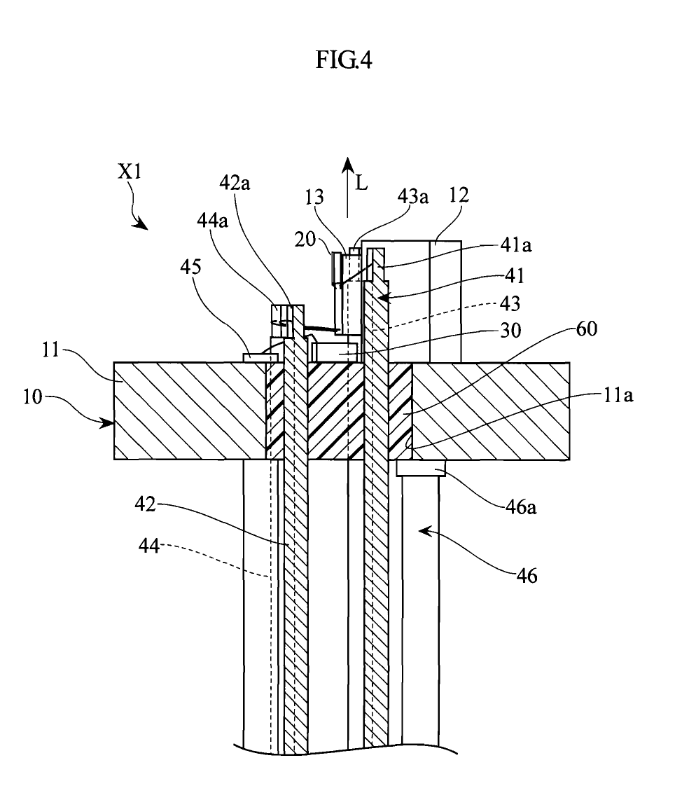

As illustrated in e.g. FIG. 4, the lead 41 extends through the opening 11a. Specifically, the lead 41 passes near the end E1 of the elongated opening 11a. The lead 41 includes a pad 41a in the form of a plate at the end located on the block portion 12 side relative to the base portion 11. The pad 41a is electrically connected to the pad 14 via a wire. Thus, the lead 41 is electrically connected to the semiconductor laser element 21 via the pad 14 and wires. In this embodiment, the lead 41 has a uniform cross section throughout the length except at the pad 41a. The cross section of the lead 41 except at the pad 41a has e.g. a circular shape having a diameter of 0.3 mm.

As illustrated in e.g. FIG. 4, the lead 42 extends through the opening 11a. Specifically, the lead 42 passes near the end E2 of the elongated opening 11a. The lead 42 includes a pad 42a in the form of a plate at the end located on the block portion 12 side relative to the base portion 11. The pad 42a is electrically connected to the pad 15 via a wire. Thus, the lead 42 is electrically connected to the semiconductor laser element 22 via the pad 15 and wires. In this embodiment, the lead 42 has a uniform cross section throughout the length except at the pad 42a. The cross section of the lead 42 except at the pad 42a has e.g. a circular shape having a diameter of 0.3 mm. The lead 42 and the above-described lead 41 pass through the same opening 11a. The lead 42 is farther from the block portion 12 than the lead 41, and thus the pad 42a of the lead 42 is farther from the block portion 12 than the pad 41a of the lead 41. In this embodiment, the pad 42a, which is relatively far from the block portion 12, is closer to the base portion 11 than the pad 41a, which is relatively close to the block portion 12.

The lead 43 extends through the opening 11b. Specifically, the lead 43 passes near the end E1 of the elongated opening 11b. The lead 43 includes a pad 43a in the form of a plate at the end located on the block portion 12 side relative to the base portion 11. The pad 43a is electrically connected to the pad 16 via a wire. Thus, the lead 43 is electrically connected to the semiconductor laser element 23 via the pad 16 and wires. In this embodiment, the lead 43 has a uniform cross section throughout the length except at the pad 43a. The cross section of the lead 43 except at the pad 43a has e.g. a circular shape having a diameter of 0.3 mm.

The lead 44 extends through the opening 11b. Specifically, the lead 44 passes near the end E2 of the elongated opening 11b. The lead 44 includes a pad 44a in the form of a plate at the end located on the block portion 12 side relative to the base portion 11. The pad 44a is electrically connected to the pad 17 via a wire. Thus, the lead 44 is electrically connected to the semiconductor laser element 24 via the pad 17 and wires. In this embodiment, the lead 44 has a uniform cross section throughout the length except at the pad 44a. The cross section of the lead 44 except at the pad 44a has e.g. a circular shape having a diameter of 0.3 mm. The lead 44 and the above-described lead 43 pass through the same opening 11b. The lead 44 is farther from the block portion 12 than the lead 43, and thus the pad 44a of the lead 44 is farther from the block portion 12 than the pad 43a of the lead 43. In this embodiment, the pad 44a, which is relatively far from the block portion 12, is closer to the base portion 11 than the pad 43a, which is relatively close to the block portion 12.

The lead 45 is the lead for the light receiving element 30 and extends through the opening 11c. The lead 45 is electrically connected to the light receiving element 30 on the base portion 11 via a wire. In this embodiment, the lead 45 has a uniform cross section throughout the length. The cross section of the lead 45 has e.g. a circular shape having a diameter of 0.45 mm.

The lead 46 is a common lead and bonded to the side of the base portion 11 which is opposite the block portion 12 via an electrically conductive bonding portion 46a. The lead 46 is electrically connected to the semiconductor laser elements 21-24 via the base portion 11 and the block portion 12 and also electrically connected to the light receiving element 30 via the base portion 11. In this embodiment, the lead 46 has a uniform cross section throughout the length. The cross section of the lead 46 has e.g. a circular shape having a diameter of 0.45 mm. In this embodiment, the cross sectional area of the lead 41 except at the pad 41a, the cross sectional area of the lead 42 except at the pad 42a, the cross sectional area of the lead 43 except at the pad 43a and the cross sectional area of the lead 44 except at the pad 44a are smaller than the cross sectional area of the lead 46, which is the common lead.

The cap 50 is provided on the base portion 11, as shown in FIG. 1, to accommodate the structure arranged above the base portion 11 in e.g. FIG. 2. In this embodiment, the cap 50 has a cylindrical side wall having an inner diameter of e.g. 45 mm. The cap 50 is bonded to the base portion 11 at the entire circumference of the side wall by resistance welding. The top surface of the cap 50, which is at the upper end in FIG. 1, is formed with an opening. The opening is closed with a glass plate attached to the cap 50. The glass plate transmits the laser beam emitted from the laser emitting portion 20 (semiconductor laser elements 21-24).

The insulating material portions 60 are provided by loading a predetermined insulating material in each of the openings 11a, 11b, and 11c. The insulating material portion 60 in the opening 11a fixes the leads 41 and 42, with the lead 41, the lead 42 and the base portion 11 spaced from each other. Thus, the lead 41, the lead 42 and the base portion 11 are electrically separated from each other. The insulating material portion 60 in the opening 11b fixes the leads 43 and 44, with the lead 43, the lead 44 and the base portion 11 spaced from each other. Thus, the lead 43, the lead 44 and the base portion 11 are electrically separated from each other. The insulating material portion 60 in the opening 11c fixes the lead 45, with the lead 45 and the base portion 11 spaced from each other. Thus, the lead 45 and the base portion 11 are electrically separated from each other. As the material of the insulating material portions 60, use may be made of low-melting glass.

In the semiconductor laser device X1, the structure which is above the base portion 11 in e.g. FIG. 2 is positioned in a space which is sealed airtight by the base portion 11 of the stem 10, the cap 50, the insulating material portions 60 and part of the leads 41-45. With this arrangement, even when the semiconductor laser device X1 is used in a humid environment, the laser emitting portion 20 (semiconductor laser elements 21-24) is not exposed to the humid environment. Thus, this arrangement is desirable for the protection of the laser emitting portion 20.

The semiconductor laser device X1 having the above-described structure is suitable for providing a high laser output, because the laser emitting portion 20 includes the plurality of semiconductor laser elements 21-24. Thus, when the semiconductor laser device X1 is used for e.g. a laser printer as a laser beam source for laser beam scanning, the printing speed enhances.

In the semiconductor laser device X1, the leads 41 and 42 extend through the same opening 11a, whereas the leads 43 and 44 extend through the same opening 11b. This arrangement in which a plurality of leads electrically connected to the semiconductor laser elements extend through a same opening of the base portion is more suitable for the size reduction of the base portion than the arrangement in which the base portion is formed with a plurality of openings, each of which is provided for the exclusive passage of only one lead of all the leads electrically connected to the semiconductor laser elements. The size reduction of the base portion leads to the size reduction of the stem, and hence, to the size reduction of the semiconductor laser device.

As described above, the semiconductor laser device X1 is suitable for the size reduction and high light emission output.

As noted before, in the semiconductor laser device X1, the opening 11a, through which the two leads 41 and 42 extend, has an elongated opening shape as illustrated in FIG. 3. This arrangement is suitable for the size reduction of the opening 11a. Further, in the semiconductor laser device X1, the opening 11b, through which the two leads 43 and 44 extend, has an elongated opening shape as illustrated in FIG. 3. This arrangement is suitable for the size reduction of the opening 11b. The size reduction of the openings 11a and 11b leads to the size reduction of the semiconductor laser device X1.

As noted before, in the semiconductor laser device X1, the cross sectional area of the lead 41 except at the pad 41a and the cross sectional area of the lead 42 except at the pad 42a are smaller than the cross sectional area of the lead 46. This arrangement is suitable for the size reduction of the opening 11a through which the leads 41 and 42 extend. Further, as noted before, in the semiconductor laser device X1, the cross sectional area of the lead 43 except at the pad 43a and the cross sectional area of the lead 44 except at the pad 44a are smaller than the cross sectional area of the lead 46. This arrangement is suitable for the size reduction of the opening 11b through which the leads 43 and 44 extend. The size reduction of the openings 11a and 11b leads to the size reduction of the semiconductor laser device X1.

As noted before, in the semiconductor laser device X1, the block portion 12 is positioned on the base portion 11 at a position between the ends E1 of the openings 11a and 11b, which are the ends on the block portion 12 side. The distance between the ends E2 of the openings 11a and 11b, which are farther from the block portion 12 than the ends E1, is smaller than the distance between the ends E1. In this way, the openings 11a and 11b as a whole are arranged to extend along the block portion 12. This arrangement is suitable for the size reduction of the base portion 11. The size reduction of the base portion 11 leads to the size reduction of the semiconductor laser device X1.

As noted before, in the leads 41 and 42 which extend through the same opening 11a in the semiconductor laser device X1, the pad 42a, which is relatively far from the block portion 12, is closer to the base portion 11 than the pad 41a, which is relatively close to the block portion 12. With this arrangement, the wire connecting the pads 14 and 41a and the wire connecting the pads 15 and 42a are prevented from crossing each other. Further, in the leads 43 and 44 which extend through the same opening 11b in the semiconductor laser device X1, the pad 44a, which is relatively far from the block portion 12, is closer to the base portion 11 than the pad 43a, which is relatively close to the block portion 12. With this arrangement, the wire connecting the pads 16 and 43a and the wire connecting the pads 17 and 44a are prevented from crossing each other. The arrangement in which the wires do not cross each other is desirable for preventing the malfunction of the semiconductor laser device X1 and preferable for the proper manufacturing of the semiconductor laser device X1.

In the semiconductor laser device X1, feedback control is performed with respect to the light intensity of the light being emitted from the laser emitting portion 20. As noted before, the monitoring laser beam is emitted from the lower end surface of the laser emitting portion 20 in FIG. 2. Upon receiving the monitoring laser beam, the light receiving element 30 outputs a signal having a magnitude corresponding to the light intensity of the light received. By utilizing the magnitude of the signal, the light intensity as the order value for the laser emitting portion 20 and the actual light intensity during the light emission can be compared. By utilizing the comparison result, the light intensity of the light being emitted from the laser emitting portion 20 is feedback controlled. The arrangement with which the feedback control is possible is desirable for achieving stable light emission from the laser emitting portion 20. In this embodiment, the output control of the laser emitting portion 20 can be performed by techniques other than feedback control. In this case, the semiconductor laser device X1 may not include the light receiving element 30.

The semiconductor laser device according to the present invention is not limited to the foregoing embodiment. The specific structure of each part of the semiconductor laser device according to the present invention may be varied in design in various ways. For instance, although the laser emitting portion 20 of the foregoing embodiment includes four semiconductor laser elements 21-24, the number of semiconductor laser elements of the laser emitting portion may be changed to two, three, five or more in accordance with the required laser beam output. The number of leads electrically connected to the semiconductor laser elements and the number of openings formed at the base portion 11 can be changed in accordance with the number of semiconductor laser elements.

Although the semiconductor laser device X1 according to the present invention is suitable for the use in a laser printer, the application of the semiconductor laser device is not limited to a laser printer. The semiconductor laser device of the present invention can be widely used as a laser beam source to be incorporated in an apparatus which utilizes a laser beam.

1. A semiconductor laser device comprising:
a plurality of semiconductor laser elements for emitting a laser beam;
a stem including a base portion and a block portion for supporting the semiconductor laser elements, the base portion including at least one opening; and
a plurality of leads extending through said at least one opening, each of the leads being electrically connected to a respective one of the semiconductor laser elements; wherein:
two or more of the leads extend through one said opening while being spaced from each other; and
the opening is filled with an insulating material.

2. The semiconductor laser device according to claim 1, wherein the opening has an elongated opening shape.

3. The semiconductor laser device according to claim 1, wherein each of the leads includes an end on a block portion side relative to the base portion, one of the ends that is relatively far from the block portion being positioned closer to the base portion than another one of the ends that is relatively close to the block portion.

4. The semiconductor laser device according to claim 1, wherein the base portion includes a plurality of openings including a first opening and a second opening each of which has an elongated opening shape, each of the first and the second openings including a first end at one end in the longitudinal direction of the opening shape and a second end at the other end in the longitudinal direction of the opening shape, the first and the second openings being spaced from each other so that the respective first ends face each other and the respective second ends face each other, the block portion being positioned on the base portion at a position between the first ends, distance between the second ends being smaller than distance between the first ends.

5. The semiconductor laser device according to claim 1, further comprising a common lead, wherein the base portion and the block portion are made of a conductive material, the common lead being attached to a side of the base portion that is opposite the block portion and electrically connected to the semiconductor laser elements via the base portion and the block portion.

6. The semiconductor laser device according to claim 5, wherein each of the leads is smaller in cross sectional area than the common lead.

7. The semiconductor laser device according to claim 1, further comprising a light receiving element and an additional lead electrically connected to the light receiving element, wherein the light receiving element is supported by the stem, the base portion of the stem including an additional opening, the additional lead extending through the additional opening, the additional opening being filled with an insulating material.
